(19) United States
(12) Patent Application Publication
(10) Pub. No.: US 2023/0230834 A1
(43) Pub. Date: Jul. 20, 2023

(54) EXTREME ULTRA-VIOLET (EUV) LITHOGRAPHY PROCESSES FOR PATTERNING PHOTORESIST AND PHOTOLITHOGRAPHY MASKS USED THEREIN

(71) Applicant: Samsung Electronics Co., Ltd., Suwon-si (KR)

(72) Inventors: Hyun Jae Lee, Seoul (KR); Hee Seung Ahn, Hwaseong-si (KR); In Seong Park, Suwon-si (KR); Yun-Ju Han, Seoul (KR)

(21) Appl. No.: 17/938,656

(22) Filed: Oct. 6, 2022

(30) Foreign Application Priority Data
Jan. 14, 2022 (KR) 10-2022-0005571

(51) Int. Cl. H01L 21/027; G03F 1/22

(52) U.S. Cl. CPC H01L 21/027; G03F 1/22; G03F 7/2004

(57) ABSTRACT

An extreme ultra-violet (EUV) lithography process includes lithographically patterning first through fourth photoresist regions on respective first through fourth regions of a semiconductor substrate, in sequence, using a mask. This mask includes a main area in which a main pattern is defined, a first dummy area in which a first dummy pattern is defined, a second dummy area in which a plurality of second sub-dummy patterns are defined at corresponding corners of the mask, and an alignment area including an alignment pattern therein that is spaced farther from a center of the main area relative to the first and second dummy areas. During the lithographically patterning, at least part of the alignment area on the first region of the substrate is exposed at least three times to EUV light, using the mask.

### REFERENCE TO PRIORITY APPLICATION

This application claims priority under 35 U.S.C. § 119 to Korean Patent Application No. 10-2022-0005571, filed Jan. 14, 2022, the disclosure of which is hereby incorporated herein by reference.

### FIELD OF THE INVENTION

The present disclosure relates to integrated circuit processing and, more particularly, to the lithography techniques used in semiconductor device manufacturing.

### BACKGROUND

In order to manufacture semiconductor devices having reduced device-to-device pitch, advanced lithography processes have been developed. For example, extreme ultraviolet (EUV) lithography processes have been proposed to manufacture semiconductor devices having smaller size and reduced device-to-device pitch. In addition, because of excessive absorption of extreme ultraviolet (EUV) radiation, extreme ultraviolet (EUV) lithography systems generally use reflective optics apparatus to perform the lithography process.

Nonetheless, a conventional extreme ultraviolet (EUV) lithography system may suffer from pattern uniformity defects. For example, a shadow effect may occur that may degrade lithography performance. Therefore, conventional extreme ultraviolet (EUV) lithography apparatus and processes may be generally suitable for an intended purpose, but may not always be satisfactory in all respects.

In particular, when a mask for the extreme ultraviolet (EUV) lithography is used, an area that is exposed to light twice or more may exist in areas where masks overlap each other. Thus, as will be understood by those skilled in the art, when the exposure is performed on the area a plurality of times, a defect may occur in a pattern formed in the corresponding area.

### SUMMARY

A technical purpose of the present disclosure is to provide a photoresist mask with improved reliability.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, there is provided a mask for a photoresist, the mask includes: a main area in which a main pattern is formed, a first dummy area surrounding the main area, wherein a first dummy pattern is formed in the first dummy area, and a plurality of second dummy areas respectively disposed in corner areas and spaced apart from the first dummy area. In addition, a second dummy pattern having a width greater than a width of the first dummy pattern is formed in each of the plurality of second dummy areas. A lithography process is performed at least three times in the second dummy area.

According to another aspect of the present disclosure, there is provided a mask for a photoresist, which includes: a first mask, and a second mask. The first mask includes a first main area, in which a first main pattern is formed, a first dummy area surrounding the first main area, a first dummy pattern formed in the first dummy area, and a plurality of second dummy areas spaced apart from the first dummy area. In addition, a second dummy pattern having a width greater than a width of the first dummy pattern is formed in each of the plurality of second dummy areas. The second mask includes a second main area in which a second main pattern is formed, a third dummy area surrounding the second main area, wherein a third dummy pattern is formed in the third dummy area, and a plurality of fourth dummy areas spaced apart from the third dummy area. A fourth dummy pattern, which has a larger width than a width of the third dummy pattern, is formed in each of the plurality of fourth dummy areas. In particular, each of the second dummy areas is disposed in each of corner areas of the first mask, and each of the fourth dummy areas is disposed in each of corner areas of the second mask. A lithography process is performed at least three times in each of the second dummy areas, and at least three times in each of the fourth dummy areas.

According to another aspect of the present disclosure, there is provided a mask for a photoresist. The mask includes first to fourth masks arranged in a first direction and a second direction intersecting each other. Each of the first to fourth masks includes a main area in which a main pattern is formed, a first dummy area surrounding the main area, a first dummy pattern formed in the first dummy area, and a plurality of second dummy areas spaced apart from the first dummy area. In addition, a second dummy pattern having a width greater than a width of the first dummy pattern is formed in each of the plurality of second dummy areas. Each of a width in the first direction and a width in the second direction of each second dummy area is in a range of 7 μm to 10 μm. The first mask is in contact with the second to fourth masks, but second mask is not in contact with the third mask, and the fourth mask is in contact with the first to third masks. Portions of the second dummy areas are respectively disposed at a corner area of the second mask and a corner area of the fourth mask, and in boundary areas between the first mask, the second mask, and the fourth mask. The other of the second dummy areas are respectively disposed in a corner area of the third mask and a corner area of the fourth mask, and in boundary areas between the first mask, the third mask, and the fourth mask. Each of the first to fourth masks includes a mask for extreme ultraviolet (EUV) lithography, and the extreme ultraviolet (EUV) lithography process is performed at least three times in each of the second dummy areas.

According to a further aspect of the present disclosure, a lithography process is provided, which includes lithographically patterning first through fourth photoresist regions on respective first through fourth regions of a semiconductor substrate, in sequence, using a mask. This mask includes a main area in which a main pattern is defined, a first dummy area in which a first dummy pattern is defined (the first dummy area at least partially surrounding the main area), and a second dummy area in which a plurality of second sub-dummy patterns are defined at corresponding corners of the mask that are spaced apart from the first dummy area. The lithographically patterning the first through fourth photoresist regions includes exposing at least part of the second dummy area on the first region of the substrate at least three times using the mask.

According to another aspect of the present disclosure, an extreme ultra-violet (EUV) lithography process includes lithographically patterning first through fourth photoresist regions on respective first through fourth regions of a semiconductor substrate, in sequence, using a mask. This mask includes a main area in which a main pattern is defined, a first dummy area in which a first dummy pattern is defined (with the first dummy area at least partially surrounding the main area), a second dummy area in which a plurality of second sub-dummy patterns are defined at corresponding corners of the mask that are spaced apart from the first dummy area, and an alignment area including an alignment pattern therein that is spaced farther from a center of the main area relative to the first and second dummy areas. The lithographically patterning the first through fourth photoresist regions includes exposing at least part of the alignment area on the first region of the substrate at least three times to EUV light, using the mask.

According to yet another aspect of the present disclosure, an extreme ultra-violet (EUV) lithography process is provided, which includes lithographically patterning first through fourth photoresist regions on respective first through fourth regions of a semiconductor substrate, in sequence, using a mask having: (i) a generally rectangular-shaped perimeter, but with three square-shaped cutouts at first, second and third corners of the mask, and (ii) an alignment area that extends as a protrusion from the fourth corner of the mask. In addition, a portion of the photoresist on the first region of the semiconductor substrate is exposed at least three times to EUV light during said lithographically patterning.

### BRIEF DESCRIPTION OF DRAWINGS

The above and other aspects and features of the present disclosure will become more apparent by describing in detail illustrative embodiments thereof with reference to the attached drawings, in which:

FIG. 1 is a schematic plan view for illustrating a mask for a photoresist according to some embodiments of the present disclosure.

FIG. 2 is a diagram to illustrate a shape of the mask for the photoresist of FIG. 1.

FIG. 3 is an enlarged view of an area P of FIG. 1.

FIG. 4 is an enlarged view of an area Q of FIG. 1.

FIG. 5 is an enlarged view of an area P and an area R of FIG. 1.

FIG. 6 is an enlarged view of an area P and an area S of FIG. 1.

FIG. 7 and FIG. 8 are diagrams for illustrating a mask for a photoresist according to some embodiments.

FIG. 9 is a schematic plan view for illustrating a mask for a photoresist according to some embodiments of the present disclosure.

FIG. 10 is a diagram to illustrate a shape of the mask for the photoresist of FIG. 9.

FIG. 11 is an enlarged view of an area T of FIG. 10.

FIG. 12 is an enlarged view of an area U of FIG. 9.

FIG. 13 and FIG. 14 are diagrams for illustrating a mask for a photoresist according to some embodiments.

FIG. 15 is a schematic cross-sectional view for illustrating a mask for a photoresist according to some embodiments.

FIG. 16 is an illustrative plan view of a semiconductor device manufactured using a mask for a photoresist according to some embodiments.

FIG. 17A and FIG. 17B are illustrative cross-sectional views taken along lines A-A and B-B in FIG. 16.

FIG. 18A and FIG. 18B are illustrative cross-sectional views taken along lines C-C and D-D of FIG. 16.

### DETAILED DESCRIPTION

Hereinafter, embodiments according to the technical idea of the present disclosure will be described with reference to the accompanying drawings.

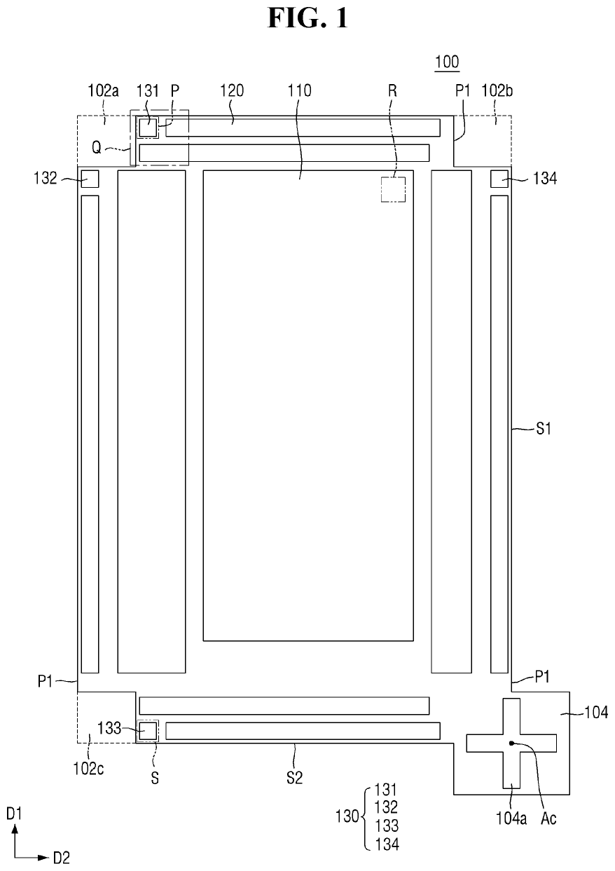

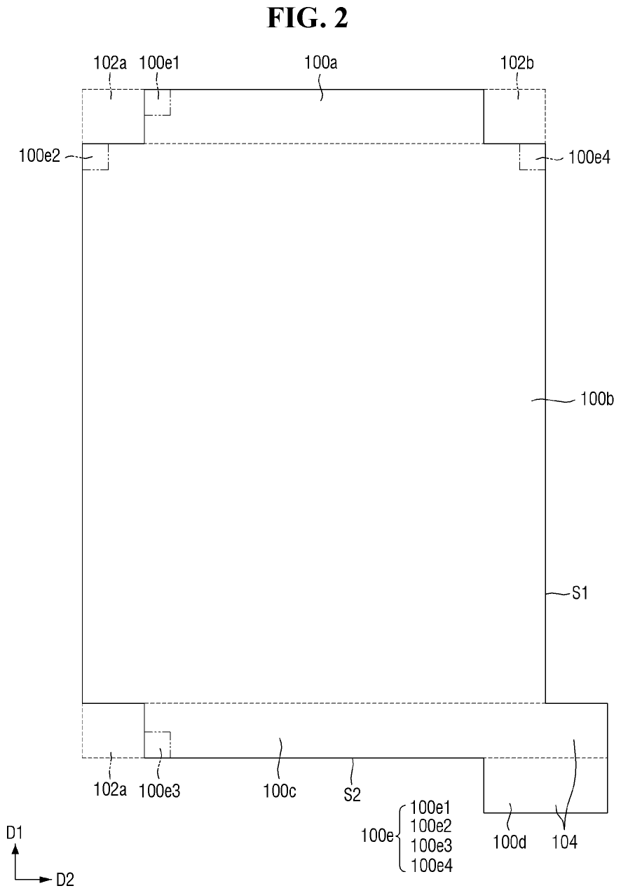

FIG. 1 is a schematic plan view of a mask for a photoresist, according to some embodiments of the present disclosure, and FIG. 2 is a diagram that illustrates a shape of the mask of FIG. 1. Referring to FIG. 2, a mask 100 for a photoresist according to some embodiments may include a first area 100a, a second area 100b, a third area 100c, and a fourth area 100d. In some embodiments, the mask 100 for the photoresist may be a mask for extreme ultraviolet (EUV) lithography, but the present disclosure is not limited thereto.

The first area 100a, the second area 100b, the third area 100c, and the fourth area 100d may be sequentially arranged in a first direction D1. For example, the first area 100a and the fourth area 100d may be disposed in an edge area, while the second area 100b and the third area 100c may be disposed between the first area 100a and the fourth area 100d. Specifically, the second area 100b may be disposed between the first area 100a and the third area 100c, and the third area 100c may be disposed between the second area 100b and the fourth area 100d, as shown. Each of the first area 100a, the second area 100b, the third area 100c, and the fourth area 100d may extend laterally in a second direction D2, which intersects and is substantially perpendicular to the first direction D1.

In some embodiments, the first area 100a may entirely overlap the second area 100b in the first direction D1. Further, a width of the first area 100a in the second direction D2 may be smaller than a width of the second area 100b in the second direction D2. A portion of the third area 100c may protrude from an end of the second area 100b in the second direction D2. A portion of the second area 100b may protrude from an end of the third area 100c in the second direction D2. A left portion of the second area 100b may protrude from the third area 100c in the second direction D2. A right portion of the third area 100c may protrude from the second area 100b in the second direction D2. The fourth area 100d may entirely overlap the third area 100c and the first direction D1. A portion of an end of the third area 100c may be coplanar with a portion of an end of the fourth area 100d.

In some embodiments, the mask 100 for the photoresist may include a corner area 100e. As used herein, a term “corner” means an area in which sides meet each other in a polyhedron. The corner area 100e may be a portion of a plurality of corners (100e1, 100e2, 100e3, 100e4) of the mask 100 for the photoresist.

In the corner area 100e, a second dummy area 130 may be disposed. The corner area 100e may include a first corner 100e1, a second corner 100e2, a third corner 100e3, and a fourth corner 100e4. The first corner 100e1 may be one of four corners of the first area 100a. For example, the first corner 100e1 may be an upper left corner of the first area 100a. The first corner 100e1 may be disposed in a portion where the first area 100a and the second area 100b do not contact each other. In the first corner 100e1, a first sub-dummy area 131 may be disposed.

The second corner 100e2 and the fourth corner 100e4 may be two of four corners of the second area 100b. For example, the second corner 100e2 may be an upper left corner of the second area 100b. The fourth corner 100e4 may be an upper right corner of the second area 100b. Each of the second corner 100e2 and the fourth corner 100e4 may be disposed in an extension of a contact line between the first area 100a and the second area 100b. In the second corner 100e2, a second sub-dummy area 132 may be disposed. In the fourth corner 100e4, a fourth sub-dummy area 134 may be disposed.

The third corner 100e3 may be one of four corners of the third area 100c. For example, the third corner 100e3 may be a lower left corner of the third area 100c. The third corner 100e3 may be disposed in a portion where the third area 100c and the second area 100b do not contact each other. The third corner 100e3 may be disposed in an extension of a contact line between the third area 100c and the fourth area 100d. In the third corner 100e3, a third sub-dummy area 133 may be disposed, as shown by FIG. 1

Subsequently, referring to FIGS. 1 and 2, the mask 100 for the photoresist according to some embodiments may include a main area 110, a first dummy area 120, and a second dummy area 130. The main area 110 may be an area in which a main pattern is formed. The main pattern may include a main gate pattern and a main active pattern. The main pattern may be, for example, a gate electrode and an active pattern of a transistor that actually operates. The main area 110 may be disposed in an inner portion of the mask 100 for the photoresist. For example, the main area 110 may be disposed in the second area 100b of the mask 100 for the photoresist, but the present disclosure is not limited thereto. Although the number of the main areas 110 is illustrated as being one, this is only for convenience of description. The technical idea of the present disclosure is not limited thereto. In another example, there may be at least two main areas 110. For convenience of description, as used herein, an example in which the number of the main areas 110 is one is described.

The first dummy area 120 may be disposed around the main area 110. The first dummy area 120 may surround the main area 110. The first dummy area 120 may be an area in which a first dummy pattern is formed. The first dummy pattern may include a first dummy gate pattern and a first dummy active pattern. The first dummy pattern may be, for example, a gate electrode and an active pattern of a transistor that does not actually operate. Although it is illustrated that the number of first dummy areas 120 surrounding the main area MR is at least two, the number, a size, and a shape of the first dummy areas 120 are not limited thereto.

The second dummy area 130 may be disposed in the corner area 100e of the mask 100 for the photoresist. The second dummy area 130 may be disposed to be spaced apart from the first dummy area 120. That is, the second dummy area 130 may be spaced apart from the first dummy area 120 in the first direction D1 and the second direction D2.

In some embodiments, the number of the second dummy areas 130 may be four. For example, the second dummy area 130 may include the first sub-dummy area 131, the second sub-dummy area 132, the third sub-dummy area 133, and the fourth sub-dummy area 134. The first sub-dummy area 131 may be disposed in the first area 100a. The first sub-dummy area 131 may be disposed in the first corner 100e1. The second sub-dummy area 132 and the fourth sub-dummy area 134 may be disposed in the second area 100b. The second sub-dummy area 132 may be disposed in the second corner 100e2. The fourth sub-dummy area 134 may be disposed in the fourth corner 100e4. The third sub-dummy area 133 may be disposed in the third area 100c. The third sub-dummy area 133 may be disposed in the third corner 100e3.

In some embodiments, the second dummy area 130 is not disposed in any corner area of the mask 100 for the photoresist. For example, the second dummy area 130 may not be disposed in upper right, lower left, and lower right corners of the first area 100a, in lower left and lower right corners of the second area 100b, and in upper left, upper right, and lower left corners of the third area 100c. Further, the second dummy area 130 is not disposed in a corner of the fourth area 100d.

In some embodiments, the second dummy area 130 may be an area in which a second dummy pattern is formed. The second dummy pattern may include a second dummy gate pattern and a second dummy active pattern. The second dummy pattern may be a gate electrode and an active pattern of a transistor that does not actually operate.

In some embodiments, the second dummy area 130 may be an area in which a lithography process is performed at least three times. A width of the second dummy pattern may be greater than each of a width of the main pattern and a width of the first dummy pattern. Accordingly, although a plurality of lithography processes are performed in the second dummy area 130, a defect may not occur in the gate electrode and the active pattern formed in the second dummy area 130.

The mask 100 is also shown as including an alignment area 104 having an alignment pattern 104a therein that is spaced farther from a center of the main area 110 relative to the first and second dummy areas 120, 130. A perimeter P1 of the mask 100 is generally rectangular-shaped, but with three square-shaped cutouts 102a, 102b, 102c at first, second and third corners of the mask 100. In contrast, the alignment area 104 extends as a protrusion from the fourth corner of the mask 100, and includes an alignment pattern 104a in the shape of a cross sign. A center A_{c} of the alignment pattern 104a is aligned to: (i) a first side S1 of the mask 100 extending in a first direction D1, and (ii) a second side S2 of the mask 100 extending in a second direction D2 orthogonal to the first direction D1.

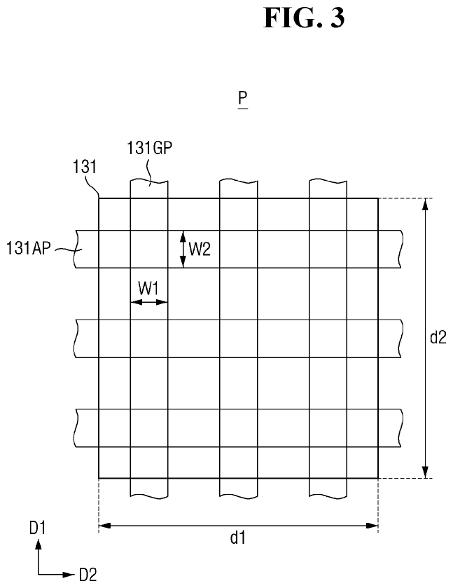

FIG. 3 is an enlarged view of a P area of FIG. 1. For reference, FIG. 3 may be an enlarged view of the first sub-dummy area 131 of FIG. 1. The first sub-dummy area 131 may be substantially the same as each of the second sub-dummy area 132, the third sub-dummy area 133, and the fourth sub-dummy area 134.

Referring to FIG. 3, the first sub-dummy area 131 may include a first sub-dummy gate pattern 131GP and a first sub-dummy active pattern 131AP. The first sub-dummy gate pattern 131GP may be the second dummy gate pattern, while the first sub-active pattern 131AP may be the second dummy active pattern.

The first sub-dummy gate pattern 131GP may extend in the first direction D1. The first sub-active pattern 131AP may extend in the second direction D2. The first sub-dummy gate pattern 131GP may intersect the first sub-active pattern 131AP.

In some embodiments, the first sub-dummy gate pattern 131GP may have a first width W1 in the second direction D2. The first width W1 may be, for example, in a range of 100 to 150 nm. Preferably, the first width W1 may be 120 nm, but the present disclosure is not limited thereto. The first sub-dummy active pattern 131AP may have a second width W2 in the first direction D1. The second width W2 may be, for example, in a range of 100 nm to 150 nm. Preferably, the second width W2 may be 120 nm, but the present disclosure is not limited thereto. The first width W1 and the second width W2 may be equal to each other. In another example, the first width W1 and the second width W2 may be different from each other.

A size of each of the first sub-dummy gate pattern 131GP and the first sub-dummy gate pattern 131AP is larger than 100 nm. Thus, even when multiple lithography processes are performed in the second dummy area 130, a defect may not occur in the pattern formed on the substrate.

In some embodiments, a width of the first sub-dummy area 131 in the second direction D2 may have a first dimension d1. A width of the first sub-dummy area 131 in the first direction D1 may have a second dimension d2. The first dimension d1 may be equal to the second dimension d2. For example, the first sub-dummy area 131 may have a square shape. However, the technical idea of the present disclosure is not limited thereto.

In some embodiments, each of the first dimension dl and the second dimension d2 may be, for example, in a range of 7 μm to 10 μ. Preferably, each of the first dimension d1 and the second dimension d2 may be about 8 pm, but the present disclosure is not limited thereto. In other words, an area of the first sub-dummy area 131 in a plane in which the first direction D1 and the second direction D2 extend may be in a range of 49 μm² to 100 μm². Preferably, the area of the first sub-dummy area 131 in the plane in which the first direction D1 and the second direction D2 extend may be in a range of 60 μm² to 70 μm². However, the technical idea of the present disclosure is not limited thereto.

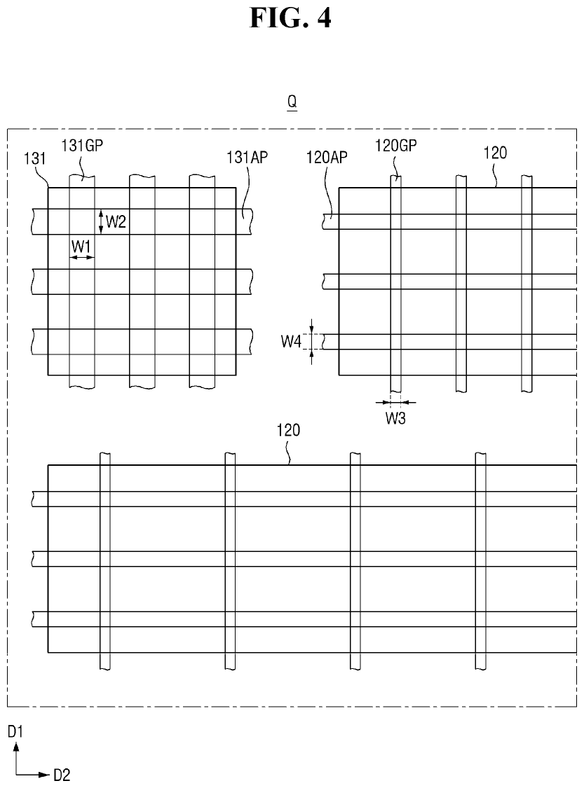

FIG. 4 is an enlarged view of a Q area of FIG. 1. For reference, FIG. 4 may be an enlarged view of the first sub-dummy area 131 and the first dummy area 120. As shown by FIG. 4, the first sub-dummy area 131 may be spaced apart from the first dummy area 120. The first sub-dummy area 131 is spaced apart from the first dummy area 120 in the first direction D1 and the second direction D2.

The first dummy area 120 may include a first dummy gate pattern 120GP and a first dummy active pattern 120AP. The first dummy gate pattern 120GP may extend in the first direction D1. The first dummy active pattern 120AP may extend in the second direction D2. The first dummy gate pattern 120GP and the first dummy active pattern 120AP may intersect each other.

The first dummy gate pattern 120GP may have a third width W3 in the second direction D2. The third width W3 of the first dummy gate pattern 120GP may be smaller than the first width W1 of the first sub-dummy gate pattern 131GP. For example, the third width W3 of the first dummy gate pattern 120GP may be in a range of 1 nm to 10 nm (i.e., 10 Å to 100 Å). Preferably, the third width W3 of the first dummy gate pattern 120GP may be about 2 nm, but present disclosure is not limited thereto.

The first dummy active pattern 120AP may have a fourth width W4 in the first direction D1. The fourth width W4 of the first dummy active pattern 120AP may be smaller than the second width W2 of the first sub-dummy active pattern 131GP. For example, the fourth width W4 of the first dummy active pattern 120AP may be in a range of 20 nm to 50 nm. Preferably, the fourth width W4 of the first dummy active pattern 120AP may be 30 nm, but the present disclosure is not limited thereto.

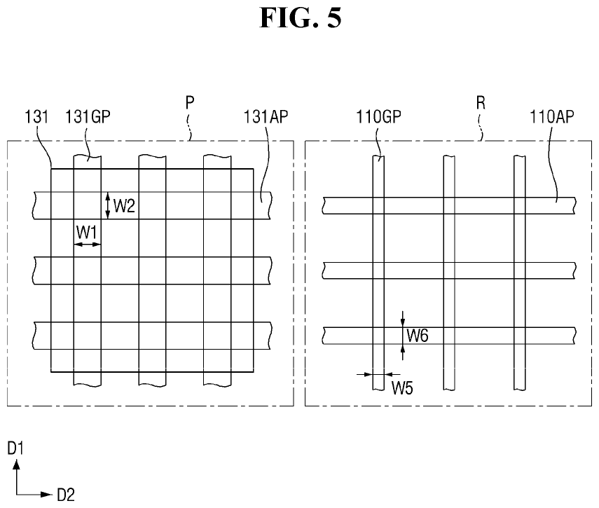

FIG. 5 is an enlarged view of a P area and a R area of FIG. 1. For reference, FIG. 5 may be an enlarged view of a portion of each of the first sub-dummy area and the main area. Referring to FIG. 5, the main pattern may be formed on the main area MR. The main pattern may include a main gate pattern 110GP and a main active pattern 110AP. The main gate pattern 110GP may extend in the first direction D1. The main active pattern 110AP may extend in the second direction D2. The main gate pattern 110GP and the main active pattern 110AP may intersect each other.

The main gate pattern 110GP may have a fifth width W5 in the second direction D2. A fifth width W5 of the main gate pattern 110GP may be smaller than the first width W1 of the first sub-dummy gate pattern 131GP. For example, the fifth width W5 of the main gate pattern 110GP may be in a range of 1 nm to 10 nm. Preferably, the fifth width W5 of the main gate pattern 110GP may be 2 nm, but the present disclosure is not limited thereto.

The main active pattern 110AP may have a sixth width W6 in the first direction D1. The sixth width W6 of the main active pattern 110AP may be smaller than the second width W2 of the first sub-dummy active pattern 131GP. For example, the sixth width W6 of the main active pattern 110AP may be in a range of 20 nm to 50 nm. Preferably, the sixth width W6 of the main active pattern 110AP may be 30 nm, but the present disclosure is not limited thereto.

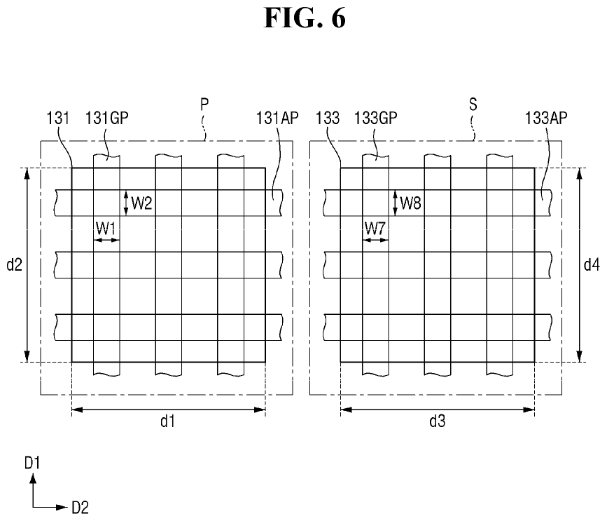

FIG. 6 is an enlarged view of a P area and a S area of FIG. 1. For reference, FIG. 6 may be an enlarged view of the first sub-dummy area 131 and the third sub-dummy area 133. Referring to FIG. 6, a size of the first sub-dummy area 131 and a size of the third sub-dummy area 133 may be equal to each other. Although not shown, a size of the first sub-dummy area 131 may be equal to each of a size of the second sub-dummy area 132 and a size of the fourth sub-dummy area 134.

For example, a width of the third sub-dummy area 133 in the second direction D2 may have a third dimension d3. A width of the third sub-dummy area 133 in the first direction D1 may have a fourth dimension d4. The third dimension d3 may be equal to the fourth dimension d4.

In some embodiments, a width of the first sub-dummy area 131 in the second direction D2 may be equal to a width of the third sub-dummy area 133 in the second direction D2. That is, the first dimension d1 may be equal to the third dimension d3. A width of the first sub-dummy area 131 in the first direction D1 may be equal to a width of the third sub-dummy area 133 in the first direction D1. That is, the second dimension d2 may be equal to the fourth dimension d4.

In some embodiments, each of the third dimension d3 and the fourth dimension d4 may be, for example, in a range of 7 μm to 10 μm. Preferably, each of the third dimension d3 and the fourth dimension d4 may be 8 μm, but the present disclosure is not limited thereto.

In some embodiments, an area of the third sub-dummy area 133 in a plane in which the first direction D1 and the second direction D2 extend may be equal to an area of the first sub-dummy area 131 in a plane in which the first direction D1 and the second direction D2 extend. For example, an area of the third sub-dummy area 133 in a plane in which the first direction D1 and the second direction D2 extend may be in a range of 49 μm² to 100 μm². Preferably, an area of the third sub-dummy area 133 in a plane in which the first direction D1 and the second direction D2 extend may be in a range of 60 μm² to 70 μm². However, the technical idea of the present disclosure is not limited thereto.

In some embodiments, a width of the first sub-dummy gate pattern 131GP and a width of the third sub-dummy gate pattern 133GP may be equal to each other. For example, the third sub-dummy gate pattern 133GP may have a seventh width W7 in the second direction D2. The seventh width W7 may be equal to the first width W1. The seventh width W7 may be, for example, in a range of 100 nm to 150 nm. Preferably, the seventh width W7 may be 120 nm, but the present disclosure is not limited thereto.

A width of the first sub-dummy active pattern 131AP and a width of the third sub-dummy active pattern 133AP may be equal to each other. For example, the third sub-dummy active pattern 133AP may have an eighth width W8 in the first direction D1. The eighth width W8 may be, for example, in a range of 100 nm to 150 nm. Preferably, the eighth width W8 may be 120 nm, but the present disclosure is not limited thereto.

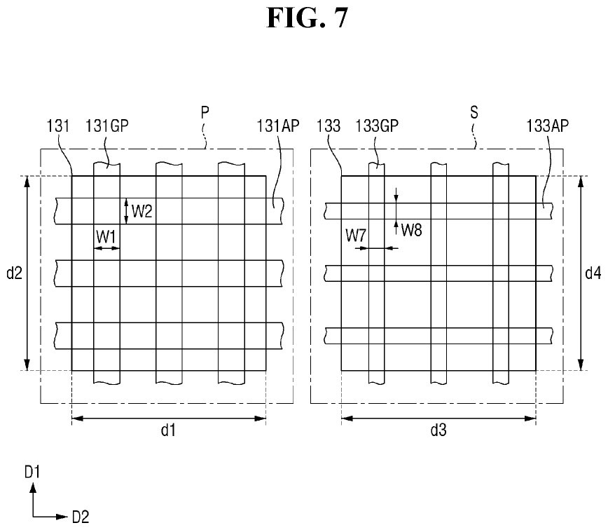

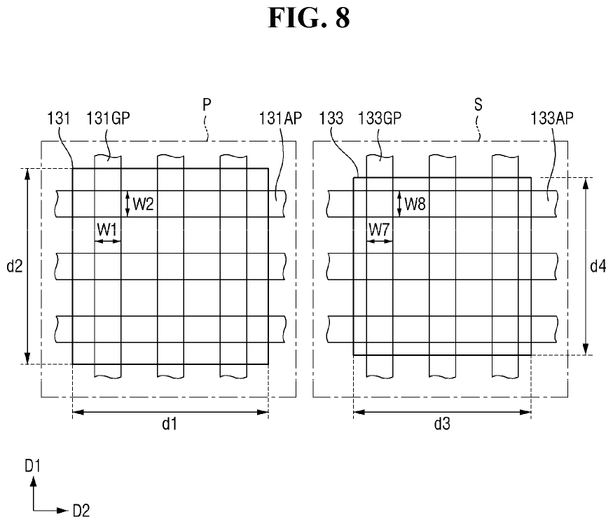

FIG. 7 and FIG. 8 are diagrams for illustrating a mask for a photoresist according to some embodiments. For convenience of description, following description is based on differences thereof from those described using FIG. 1 to FIG. 6. First, referring to FIG. 7, a width of the first sub-dummy gate pattern 131GP and a width of the third sub-dummy gate pattern 133GP may be different from each other. A width of the first sub-dummy active pattern 131AP and a width of the third sub-dummy active pattern 133AP may be different from each other. That is, widths of the second dummy patterns formed in the second dummy area 130 may be different from each other.

For example, the first width W1 may be different from the seventh width W7. The second width W2 may be different from the eighth width W8. The widths of the first to fourth sub-dummy patterns may be different from each other. For example, the first width W1 may be greater than the seventh width W7, and the second width W2 may be greater than the eighth width W8, but the present disclosure is not limited thereto.

Referring to FIG. 8, a size of the first sub-dummy area 131 may be different from a size of the third sub-dummy area 133. For example, a width of the first sub-dummy area 131 in the second direction D2 may be greater than a width of the third sub-dummy area 133 in the second direction D2. That is, the first dimension d1 may be greater than the third dimension d3. A width of the first sub-dummy area 131 in the first direction D1 may be greater than a width of the third sub-dummy area 133 in the first direction D1. That is, the second dimension d2 may be greater than the fourth dimension d4. However, the technical idea of the present disclosure is not limited thereto.

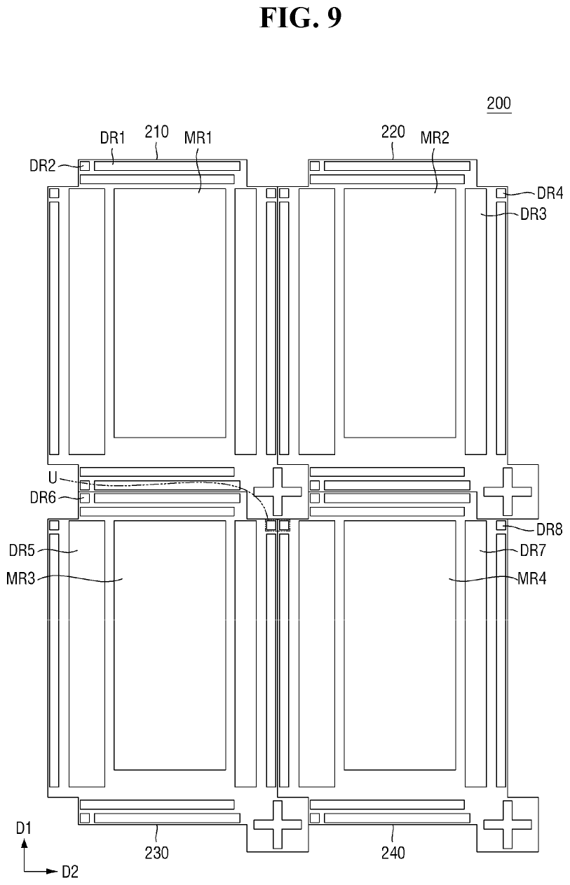

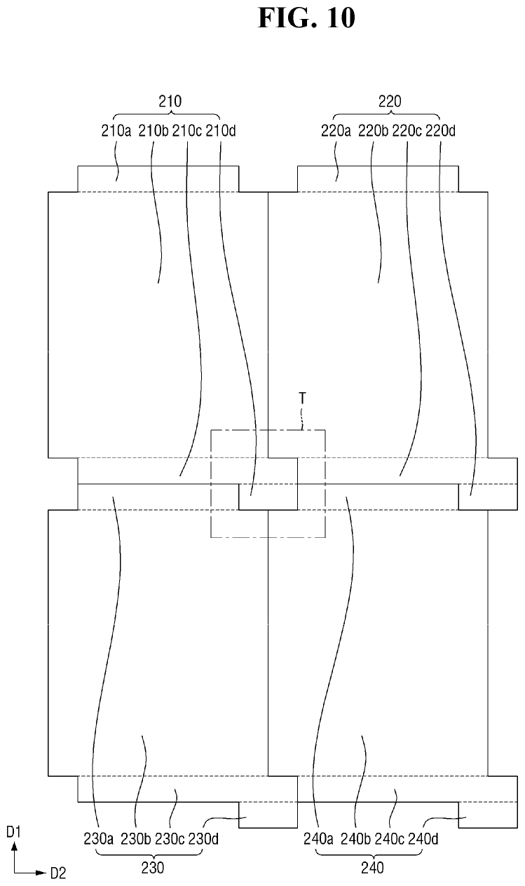

FIG. 9 is a schematic plan view for illustrating a mask for a photoresist according to some embodiments of the present disclosure. FIG. 10 is a diagram to illustrate a shape of the mask for the photoresist of FIG. 9. For convenience of description, following description is based on differences thereof from those described with respect to the embodiments of FIGS. 1 through 6.

Referring to FIG. 9 and FIG. 10, a mask 200 for a photoresist according to some embodiments may include first to fourth masks 210, 220, 230, and 240. Each of the first to fourth masks 210, 220, 230, and 240 may act as a mask for extreme ultraviolet (EUV) lithography, but the disclosure is not limited to only EUV masks.

The first to fourth masks 210, 220, 230, and 240 may be arranged with each other in the first direction D1 and the second direction D2. For example, the first mask 210 and the second mask 220 may be arranged in the second direction D2. The third mask 230 and the fourth mask 240 may be arranged in the second direction D2. The first mask 210 and the third mask 230 may be arranged in the first direction D1. The second mask 220 and the fourth mask 240 may be arranged in the first direction D1.

The first to fourth masks 210, 220, 230, and 240 may be in contact with each other. For example, the first mask 210 may be in contact with the second to fourth masks 220, 230, and 240. The second mask 220 may be in contact with the first mask 210 and the fourth mask 240. The second mask 220 does not contact the third mask 230. The third mask 230 may be in contact with the first mask 210 and the fourth mask 240. The third mask 230 does not contact the second mask 220. The fourth mask 240 may be in contact with the first to third masks 210, 220, and 230.

The first mask 210 may include first to fourth areas 210a, 210b, 210c, and 210d. The second mask 220 may include first to fourth areas 220a, 220b, 220c, and 220d. The third mask 230 may include first to fourth areas 230a, 230b, 230c, and 230d. The fourth mask 240 may include first area to fourth areas 240a, 240b, 240c, and 240d. The first to fourth masks 210, 220, 230, and 240 may have the same shape.

In some embodiments, the second area 210b of the first mask 210 may contact the second area 220b of the second mask 220. The third area 210c of the first mask 210 may be in contact with the third area 220c of the second mask 220 and the first area 230a of the third mask 230. The fourth area 210d of the first mask 210 may be in contact with the first area 230a of the third mask 230, the second area 230b of the third mask 230, the first area 240a of the fourth mask 240, and the second area 240b of the fourth mask 240.

In some embodiments, the first mask 210 may include a first main area MR1, a first dummy area DR1, and a second dummy area DR2. The second mask 220 may include a second main area MR2, a third dummy area DR3, and a fourth dummy area DR4. The third mask 230 may include a third main area MR3, a fifth dummy area DRS, and a sixth dummy area DR6. The fourth mask 240 may include a fourth main area MR4, a seventh dummy area DR7, and an eighth dummy area DR8.

Each of the first to fourth main areas MR1, MR2, MR3, and MR4 may be an area in which a transistor(s) that actually operates is formed. Each of the first to eighth dummy areas DR1, DR2, DR3, DR4, DRS, DR6, DR7, and DR8 may be an area in which a dummy transistor(s) that does not operate is formed.

The second dummy area DR2 may be spaced apart from the first dummy area DR1. The second dummy area DR2 may be disposed in a corner area of the first mask 210. The fourth dummy area DR4 may be spaced apart from the third dummy area DR3. The fourth dummy area DR4 may be disposed in a corner area of the second mask 220. The sixth dummy area DR6 may be spaced apart from the fifth dummy area DRS. The sixth dummy area DR6 may be disposed in a corner area of the third mask 230. The eighth dummy area DR8 may be spaced apart from the seventh dummy area DR7. The eighth dummy area DR8 may be disposed in a corner area of the fourth mask 240.

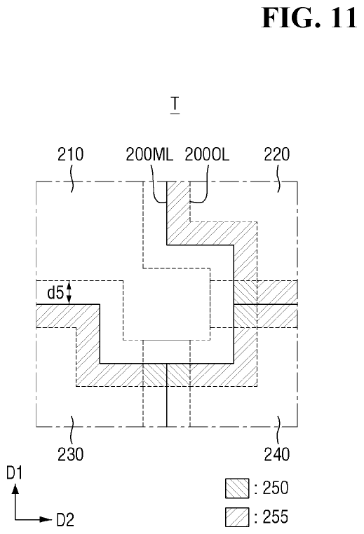

FIG. 11 is an enlarged view of a T area of FIG. 10. With reference to FIG. 11, an exposure overlapping area according to some embodiments will be described. Referring to FIG. 11, the first to fourth masks 210, 220, 230, and 240 of the mask 200 for the photoresist according to some embodiments may be in contact with each other at the fourth area 210d of the first mask 210.

In some embodiments, in portions where the first to fourth masks 210, 220, 230, and 240 are in contact with each other, exposure overlapping areas 250 and 255 may be formed. The exposure overlapping areas 250 and 255 may be areas in which the lithography process is performed multiple times. For example, the exposure overlapping areas 250 and 255 may include a double overlapping area 255 and a triple overlapping area 250. The double overlapping area 255 may be an area where the lithography process is performed twice, whereas the triple overlapping area 250 may be an area in which the lithography process is performed three times.

For example, when the lithography process is performed using the mask 200 for the photoresist according to some embodiments as an etching mask, a total of four times of lithography processes may be performed. Sequentially, a lithography process may be performed once using the first mask 210, a lithography process may be performed a second time using the second mask 220, a lithography process may be performed a third time using the third mask 230, and a lithography process may be performed a fourth time using the fourth mask 240.

In FIG. 11, a first line 200ML may be a line contacting the first mask 210, the second mask 220, the third mask 230, and the fourth mask 240. A second line 200OL may be a boundary line of an irradiation area for the exposure when a lithography process is performed using the first to fourth masks 210, 220, 230, and 240 as an etching mask. For example, even when a lithography process is performed using the first mask 210 as an etching mask, light may be irradiated to the second line 200OL.

In some embodiments, the first line 200ML and the second line 200OL may be spaced apart from each other by a fifth dimension d5. The fifth dimension d5 may be, for example, in a range of 7 μm to 10 μm. Preferably, the fifth dimensions d5 may be 8 μm, but the present disclosure is not limited thereto.

That is, when a lithography process is performed using the mask 200 for the photoresist according to some embodiments as an etching mask, the light may be irradiated to a boundary line of the mask 200 for the photoresist, for example, the second line 200OL which may be spaced apart, by the fifth dimension d5, from the first line 200ML.

In some embodiments, the double overlapping area 255 may include an area which is exposed to light twice when the lithography process is performed using the first mask 210 and the second mask 220, an area which is exposed to light twice when the lithography process is performed using the first mask 210 and the third mask 230, and an area which is exposed to light twice when the lithography process is performed using the first mask 210 and the fourth mask 240. The triple overlapping area 250 may include an area which is exposed to light three times when the lithography process is performed using the first mask 210, the second mask 220, and the fourth mask 240, and an area which is exposed to light three times when the lithography process is performed using the first mask 210, the third mask 230 and the fourth mask 240.

Referring to FIG. 9 and FIG. 11, the fourth dummy area DR4, the sixth dummy area DR6, and the eighth dummy area DR8 may be disposed in the triple overlapping area 250. Although not shown, the second dummy area DR2 may be disposed in the triple overlapping area 250.

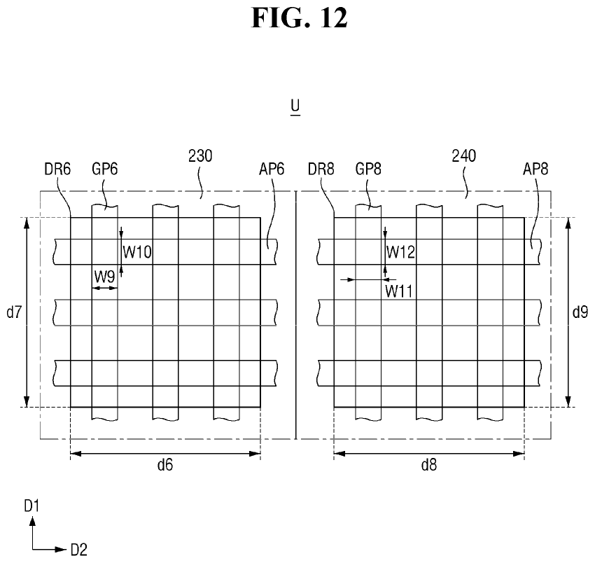

FIG. 12 is an enlarged view of a U area of FIG. 9. For reference, FIG. 12 may be an enlarged view of a portion of each of the sixth dummy area DR6 and the eighth dummy area DR8. Referring to FIG. 12, a size of the sixth dummy area DR6 and a size of the eighth dummy area DR8 may be equal to each other. Although not shown, each of a size of the second dummy area DR2 and a size of the fourth dummy area DR4 may be equal to a size of the sixth dummy area DR6.

For example, a width of the sixth dummy area DR6 in the second direction D2 may have a sixth dimension d6. A width of the sixth dummy area DR6 in the first direction D1 may have a seventh dimension d7. The sixth dimension d6 may be equal to the seventh dimension d7.

A width of the eighth dummy area DR8 in the second direction D2 may have an eighth dimension d8. A width of the eighth dummy area DR8 in the first direction D1 may have a ninth dimension d9. The eighth dimension d8 may be equal to the ninth dimension d9.

In some embodiments, a width of the sixth dummy area DR6 in the second direction D2 may be equal to a width of the eighth dummy area DR8 in the second direction D2. A width of the sixth dummy area DR6 in the first direction D1 may be equal to a width of the eighth dummy area DR8 in the first direction D1. That is, the sixth dimension d6 may be equal to the eighth dimension d8. The seventh dimension d7 may be equal to the ninth dimension d9.

In some embodiments, each of the sixth dimension d6, the seventh dimension d7, the eighth dimension d8, and the ninth dimension d9 may be, for example, in a range of 7 μm to 10 μm. Preferably, each of the sixth dimension d6, the seventh dimension d7, the eighth dimension d8, and the ninth dimension d9 may be 8 μm, but the present disclosure is not limited thereto.

In some embodiments, an area of the sixth dummy area DR6 in the plane in which the first direction D1 and the second direction D2 extend may be equal to an area of the eighth dummy area DR8 in the plane in which the first direction D1 and the second direction D2 extend. For example, each of the area of the sixth dummy area DR6 and the area of the eighth dummy area DR8 in the plane in which the first direction D1 and the second direction D2 extend may be in a range of 49 μm² to 100 μm². Preferably, each of the area of the sixth dummy area DR6 and the area of the eighth dummy area DR8 in the plane in which the first direction D1 and the second direction D2 extend may be in a range of 60 μm² to 70 μm². However, the technical idea of the present disclosure is not limited thereto.

In some embodiments, the sixth dummy area DR6 may include a sixth dummy gate pattern GP6 and a sixth dummy active pattern AP6. The eighth dummy area DR8 may include an eighth dummy gate pattern GP8 and an eighth dummy active pattern AP8.

A width of the sixth dummy gate pattern GP6 and a width of the eighth dummy gate pattern GP8 may be equal to each other. For example, the sixth dummy gate pattern GP6 may have a ninth width W9 in the second direction D2. The eighth dummy gate pattern GP8 may have an eleventh width W11 in the second direction D2. The ninth width W9 may be equal to the eleventh width W11. Each of the ninth width W9 and the eleventh width W11 may be, for example, in a range of 100 nm to 150 nm. Preferably, each of the ninth width W9 and the eleventh width W11 may be 120 nm, but the present disclosure is not limited thereto.

A width of the sixth dummy active pattern AP6 and a width of the eighth dummy active pattern AP8 may be equal to each other. For example, the sixth dummy active pattern AP6 may have a tenth width W10 in the first direction D1. The eighth dummy active pattern AP8 may have a twelfth width W12 in the first direction D1. Each of the tenth width W10 and the twelfth width W12 may be, for example, in a range of 100 nm to 150 nm. Preferably, each of the tenth width W10 and the twelfth width W12 may be 120 nm, but the present disclosure is not limited thereto.

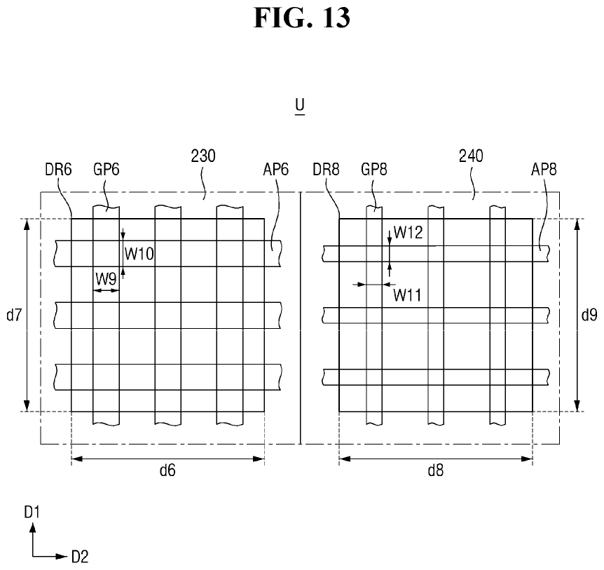

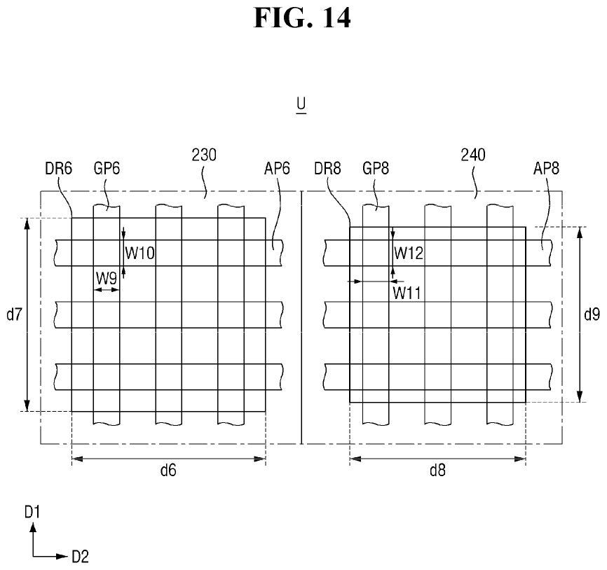

FIG. 13 and FIG. 14 are diagrams for illustrating a mask for a photoresist according to some embodiments. For convenience of description, following description is based on differences thereof from those described using FIG. 9 to FIG. 12. Referring now to FIG. 13, a width of the sixth dummy gate pattern GP6 and a width of the eighth dummy gate pattern GP8 may be different from each other. A width of the sixth dummy active pattern AP6 and a width of the eighth dummy active pattern AP8 may be different from each other.

For example, the ninth width W9 may be different from the eleventh width W11. The tenth width W10 may be different from the twelfth width W12. The ninth width W9 may be greater than the eleventh width W11, and the tenth width W10 may be greater than the twelfth width W12, but the present disclosure is not limited thereto.

Referring to FIG. 14, a size of the sixth dummy area DR6 may be different from a size of the eighth dummy area DR8. For example, a width of the sixth dummy area DR6 in the second direction D2 may be greater than a width of the eighth dummy area DR8 in the second direction D2. That is, the sixth dimension d6 may be greater than the eighth dimension d8. A width of the sixth dummy area DR6 in the first direction D1 may be greater than a width of the eighth dummy area DR8 in the first direction D1. That is, the seventh dimension d7 may be greater than the ninth dimension d9. However, the technical idea of the present disclosure is not limited thereto.

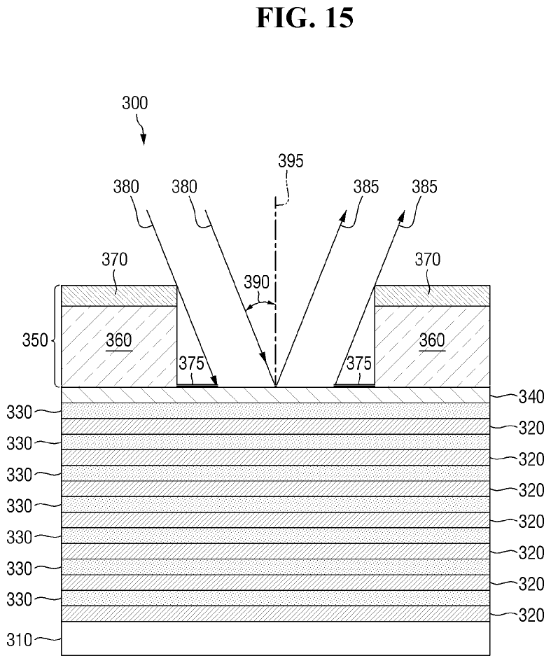

FIG. 15 is a schematic cross-sectional view for illustrating a mask for a photoresist according to some embodiments. Referring to FIG. 15, a simplified schematic partial sectional view of a mask 300 for the photoresist is shown. The mask 300 for the photoresist may be implemented as one embodiment of a multi-layer mask for a mask apparatus.

In some embodiments, the mask 300 for the photoresist may include a silicon substrate 310. A plurality of silicon layers 320 and a plurality of molybdenum layers 330 may be stacked on the silicon substrate 310. The plurality of silicon layers 320 and the plurality of molybdenum layers 330 may be alternately stacked on the silicon substrate 310. That is, a molybdenum layer 330 may be disposed on a silicon layer 320, and then another silicon layer 320 may be disposed on the molybdenum layer 330. The ruthenium layer 340 may be disposed on a stack in which the silicon layers 320 and the molybdenum layers 330 are alternately stacked with each other.

The mask 300 for the photoresist may further include a plurality of layout patterns 350. The layout pattern 350 may represent a semiconductor element feature to be patterned on a semiconductor wafer, for example, a gate line for a metal oxide semiconductor (MOS) transistor. For example, the layout pattern 350 may include a tantalum boron nitride layer 360 and a lawrencium layer 370. However, this is only for convenience of description, and a material and a composition for the mask 300 for the photoresist may be modified according to further embodiments.

The extreme ultraviolet (EUV) lithography system may irradiate light 380 toward the mask 300 for the photoresist. The light 380 may be, for example, an extreme ultraviolet (EUV) radiation beam generated from a light source device. The light 380 may be irradiated at a non-incident angle towards the mask 300 for the photoresist. That is, the light 380 may be irradiated obliquely toward the mask 300 for the photoresist to form an incident angle of 390 relative to a vertical axis 395 perpendicular to a surface of the mask 300 for the photoresist. The light 380 may be reflected from a surface of the ruthenium layer 340 to generate reflected light 385. The reflected light 385 may be projected toward a projection optics (not shown) to perform an extreme ultraviolet (EUV) lithography process in a range of about 5 ° to about 7 °. However, since the layout pattern 350 has a constant vertical dimension and the light 380 or the reflected light 385 may form the incident angle 390 relative to the vertical axis 395, a shadow 375 may be formed on the surface of the mask 300 for the photoresist. This is referred to as a shadow effect or a shadow bias.

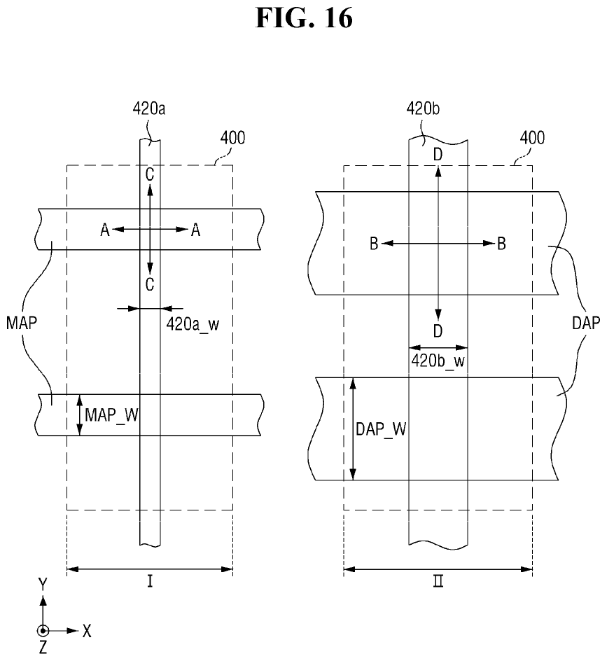

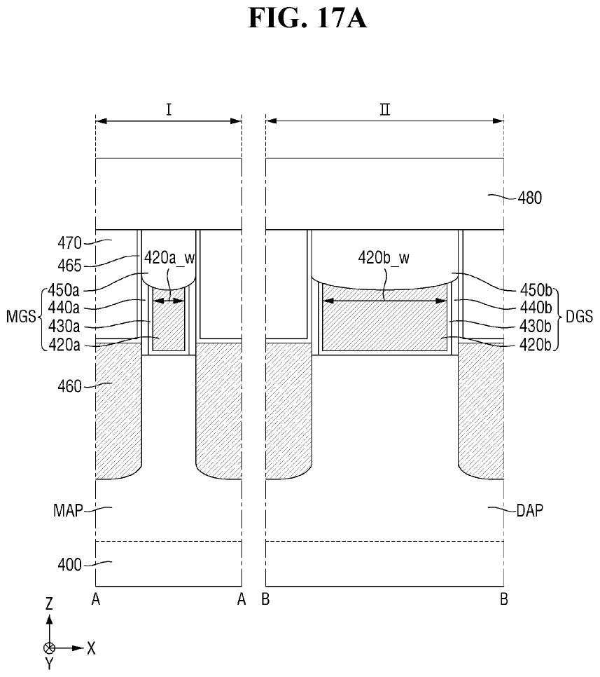

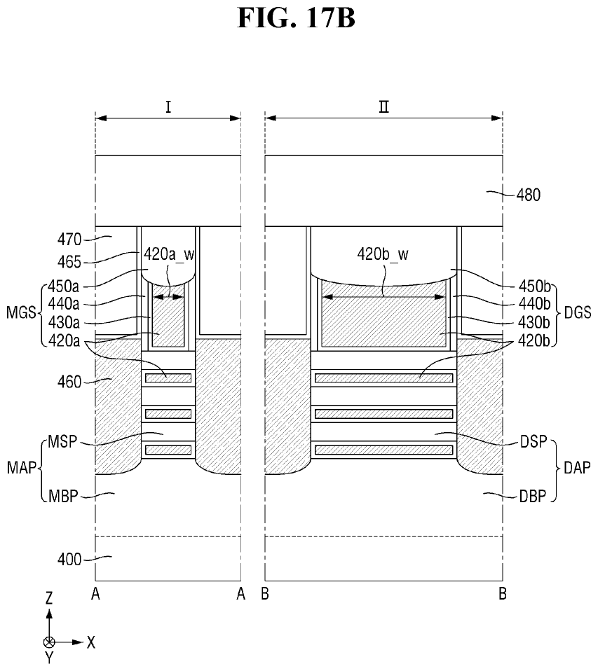

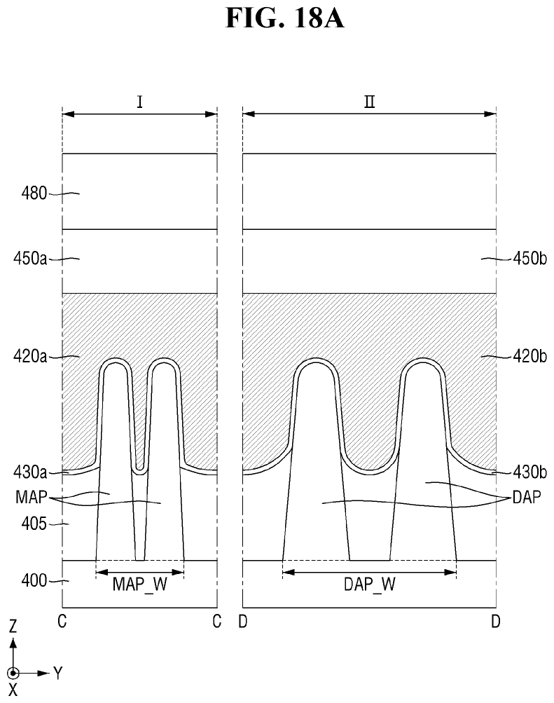

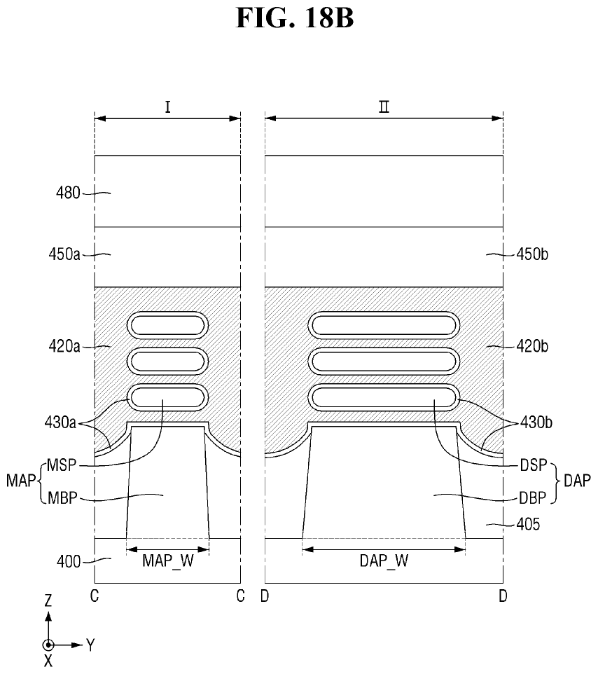

FIG. 16 is an illustrative plan view of a semiconductor device manufactured using a mask for a photoresist according to some embodiments. FIG. 17A and FIG. 17B are illustrative cross-sectional views taken along lines A-A and B-B in FIG. 16. FIG. 18A and FIG. 18B are illustrative cross-sectional views taken along lines C-C and D-D of FIG. 16. Referring to FIG. 16 to FIG. 18B, a semiconductor device manufactured using a mask for a photoresist according to some embodiments may include a first area I and a second area II. The first area I may be the main area 110 of FIG. 1, however, the second area II may be the second dummy area 130 of FIG. 1.

The semiconductor device according to some embodiments may include a substrate 400, a field insulating film 405, a main gate electrode 420a, a dummy gate electrode 420b, a main active pattern MAP, and a dummy active pattern DAP. Although not shown, the substrate 400 may include an active area and a field area. The field area may be formed between adjacent active areas. The active area may be an area in which the main active pattern MAP and the dummy active pattern DAP are disposed. The field area and the active area may define a boundary line therebetween. The active areas may be spaced from each other via the field area.

In other words, an element isolation film may be disposed around a plurality of active areas that are spaced apart from each other. In this regard, a portion of the element isolation film between the active areas may be the field area. For example, a portion in which a channel area of a transistor that may be one example of a semiconductor device is formed may the active area. A portion defining the channel area of the transistor formed in the active area may be the field area. Alternatively, the active area may be a portion in which a fin-shaped pattern or a nanosheet used as a channel area of a transistor is formed, while the field area may be an area in which the fin-shaped pattern or the nanosheet used as the channel area is not formed.

The substrate 400 may be a silicon substrate or an (SOI) silicon-on-insulator. Alternatively, the substrate 400 may include silicon germanium, SGOI (silicon germanium on insulator), indium antimonide, lead telluride compound, indium arsenide, indium phosphide, gallium arsenide, or gallium antimonide, but the present disclosure is not limited thereto.

The main active pattern MAP may protrude from a portion of the substrate 400 in the first area I. The main active pattern MAP may extend along the third direction X and on the substrate 400 and in the first area I. For example, the main active pattern MAP may include a long side extending in a third direction X and a short side extending in a fourth direction Y. In this regard, the third direction X may intersect the fourth direction Y and a fifth direction Z. Further, the fourth direction Y may intersect the fifth direction Z.

The dummy active pattern DAP may protrude from a portion of the substrate 400 in the second area II. The dummy active pattern DAP may extend along the third direction X and on the substrate 400 and in the second area II. For example, the dummy active pattern DAP may include a long side extending in the third direction X and a short side extending in the fourth direction Y. Each of the main active pattern MAP and the dummy active pattern DAP may be a multi-channel active pattern. In a semiconductor device according to some embodiments, each of the main active pattern MAP and the dummy active pattern DAP may be a corresponding fin-shaped pattern, or may include a lower pattern and a sheet pattern.

For example, in FIG. 17A and FIG. 18A, each of the main active pattern MAP and the dummy active pattern DAP may be a fin-shaped pattern. In FIG. 17B and FIG. 18B, the main active pattern MAP may include a main lower pattern MBP, and a plurality of main sheet patterns MSP. The main sheet pattern MSP may be spaced apart from the main lower pattern MBP in the fifth direction Z. The main dummy active pattern DAP may include a dummy lower pattern DBP and a plurality of dummy sheet patterns DSP. The dummy sheet pattern DSP may be spaced apart from the dummy lower pattern DBP in the fifth direction Z. Although each of the number of the main sheet patterns MSP and the number of the dummy sheet patterns DSP is illustrated as being three, this is only for convenience of illustration. The technical idea of the present disclosure is not limited thereto.

When the main active pattern MAP and the dummy active pattern DAP are formed using a mask for a photoresist according to some embodiments, a width MAP_W in the fourth direction Y of the main active pattern MAP may be smaller than a width DAP_W in the fourth direction Y of the dummy active pattern DAP. For example, a width MAP_W in the fourth direction Y of the main active pattern MAP may be in a range of 20 nm to 50 nm. A width DAP_W in the fourth direction Y of the dummy active pattern DAP may be in a range of 100 nm to 150 nm.

Each of the main active pattern MAP and the dummy active pattern DAP may be a portion of the substrate 400, or may include an epitaxial layer grown from the substrate 400. Each of the main active pattern MAP and the dummy active pattern DAP may include, for example, silicon or germanium as an elemental semiconductor material. Further, each of the main active pattern MAP and the dummy active pattern DAP may include a compound semiconductor. For example, the compound semiconductor may include a group IV-IV compound semiconductor or a group III-V compound semiconductor.

The group IV-IV compound semiconductor may include, for example, a binary compound including two of carbon (C), silicon (Si), germanium (Ge), and tin (Sn), a ternary compound including three thereof, or a compound obtained by doping a group IV element thereto. In some embodiments, the group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with each other, a ternary compound obtained by combining two of aluminum (Al), gallium (Ga), and indium (In) as a group III element and one of phosphorus (P), arsenic (As), and antimony (Sb) as a group V with each other, or a quaternary compound obtained by combining three of aluminum (Al), gallium (Ga), and indium (In) as a group III element and one of phosphorus (P), arsenic (As), and antimony (Sb) as a group V with each other.

In FIG. 18A, a field insulating film 405 may be formed on a portion of a sidewall of the main active pattern MAP and a portion of a sidewall of the dummy active pattern DAP. In FIG. 18B, the field insulating film 405 may be formed on a portion of a sidewall of the main lower pattern MBP and a portion of a sidewall of the dummy lower pattern DBP. Each of the main lower pattern MBP and the dummy lower pattern DBP may protrude upwardly beyond a top face of the field insulating film 405. The field insulating film 405 may include, for example, an oxide film, a nitride film, an oxynitride film, or a combination film thereof.

A main gate structure MGS may be disposed on the substrate 400 and in the first area I. The main gate structure MGS may extend in the fourth direction Y. The main gate structure MGS may be disposed on the field insulating film 405. The main gate structure MGS may be disposed on the main active pattern MAP. The main gate structure MGS may intersect the main active pattern MAP.

A dummy gate structure DGS may be disposed on substrate 400 and in the second area II. The dummy gate structure DGS may extend in the fourth direction Y. The dummy gate structure DGS may be disposed on the field insulating film 405. The dummy gate structure DGS may be disposed on the dummy active pattern DAP. The dummy gate structure DGS may intersect the dummy active pattern DAP.

The main gate structure MGS may include, for example, a main gate electrode 420a, a main gate insulating film 430a, a main gate spacer 440a, and a main gate capping pattern 450a. The dummy gate structure DGS may include, for example, a dummy gate electrode 420b, a dummy gate insulating film 430b, a dummy gate spacer 440b, and a dummy gate capping pattern 450b.

The main gate electrode 420a may be formed on the main active pattern MAP. The main gate electrode 420a may intersect the main active pattern MAP. In FIG. 17A, the main gate electrode 420a is formed on the main active pattern MAP. In FIG. 17B, the main gate electrode 420a is disposed on the main lower pattern MBP so as to surround the main sheet pattern MSP. The dummy gate electrode 420b may be formed on the dummy active pattern DAP. The dummy gate electrode 420b may intersect the dummy active pattern DAP. In FIG. 17A, the dummy gate electrode 420b is formed on the dummy active pattern DAP. In FIG. 17B, the dummy gate electrode 420b may be disposed on the dummy lower pattern DBP so as to surround the dummy sheet pattern DSP.

In some embodiments, a width 420a_W in the third direction X of the main gate electrode 420a may be smaller than a width 420b_W in the third direction X of the dummy gate electrode 420b. For example, when the main gate electrode 420a and the dummy gate electrode 420b are formed using the photoresist mask according to some embodiments, a width of the main gate electrode 420a may be smaller than a width 420b of the dummy gate electrode. A width 420b_W of the main gate electrode 420a in the third direction X may be, for example, in a range of 1 nm to 10 nm. A width 420b_W of the dummy gate electrode 420b in the third direction X may be, for example, in a range of 100 nm to 150 nm.

Each of the main gate electrode 420a and the dummy gate electrode 420b may include, for example, at least one of Titanium Nitride (TiN), Tantalum Carbide (TaC), Tantalum Nitride (TaN), Titanium Silicon Nitride (TiSiN), Tantalum Silicon Nitride (TaSiN), Tantalum Titanium Nitride (TaTiN), Titanium Aluminum Nitride (TiAlN), Tantalum Aluminum Nitride (TaAlN), Tungsten Nitride (WN), Ruthenium (Ru), Titanium Aluminum (TiAl), Titanium Aluminum Carbonitride (TiAlC—N), Titanium Aluminum Carbide (TiAlC), Titanium Carbide (TiC), Tantalum Carbonitride (TaCN), Tungsten (W), Aluminum (Al), Copper (Cu), Cobalt (Co), Titanium (Ti), Tantalum (Ta), Nickel (Ni), Platinum (Pt), Nickel Platinum (Ni—Pt), Niobium (Nb), Niobium Nitride (NbN), Niobium Carbide (NbC), Molybdenum (Mo), Molybdenum Nitride (MoN), Molybdenum Carbide (MoC), Tungsten Carbide (WC), Rhodium (Rh), Palladium (Pd), Iridium (Ir), Osmium (Os), Silver (Ag), Gold (Au), Zinc (Zn), Vanadium (V), and combinations thereof.

The main gate spacer 440a may be disposed on a sidewall of the main gate electrode 420b. The dummy gate spacer 440b may be disposed on a sidewall of the dummy gate electrode 440b. Each of the main gate spacer 440a and the dummy gate spacer 440b may include, for example, at least one of silicon nitride (SiN), silicon oxynitride (SiON), silicon oxide (SiO₂), silicon oxycarbonitride (SiOCN), silicon boron nitride (SiBN), silicon boron oxynitride (SiOBN), silicon oxycarbide (SiOC), and combinations thereof.

The main gate insulating film 430a may extend along a sidewall and a bottom face of the main gate electrode 420a. The main gate insulating film 430a may be formed on the main active pattern MAP. The main gate insulating film 430a may be formed between the main gate electrode 420a and the main gate spacer 440a. In FIG. 18B, the main gate insulating film 430a may extend along a top face of the main lower pattern MBP and a top face of the field insulating film 405. The main gate insulating film 430a may surround the main sheet pattern MSP.

The dummy gate insulating film 430b may extend along a sidewall and a bottom face of the dummy gate electrode 420b. The dummy gate insulating film 430b may be formed on the dummy active pattern DAP. The dummy gate insulating film 430b may be formed between the dummy gate electrode 420b and the dummy gate spacer 440b. In FIG. 18B, the dummy gate insulating film 430b may extend along a top face of the dummy lower pattern DBP and a top face of the field insulating film 405. The dummy gate insulating film 430b may surround the dummy sheet pattern DSP.

Each of the main gate insulating film 430a and the dummy gate insulating film 430b may include silicon oxide, silicon oxynitride, silicon nitride, or a high dielectric constant material having a higher electrical constant than that of silicon oxide. The high dielectric constant materials may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments may include an NC (negative capacitance) FET using a negative capacitor. For example, each of the main gate insulating film 430a and the dummy gate insulating film 430b may include a ferroelectric material film having ferroelectric characteristics and a paraelectric material film having paraelectric characteristics.

The ferroelectric material film may have negative capacitance, whereas the paraelectric material film may have positive capacitance. For example, when two or more capacitors may be connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. In this connection, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O).

The ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one of gadolinium (Gd), silicon (Si), zirconium (Zr), aluminum (Al), and yttrium (Y). When the dopant is aluminum (Al), the ferroelectric material film may contain about 3 to about 8 at % (atomic %) of aluminum. In this connection, a content of the dopant may be a content of aluminum based on a sum of hafnium and aluminum.

When the dopant is silicon (Si), the ferroelectric material film may contain about 2 to about 10 at % of silicon. When the dopant is yttrium (Y), the ferroelectric material film may contain about 2 to about 10 at % yttrium. When the dopant is gadolinium (Gd), the ferroelectric material film may contain about 1 to about 7 at % gadolinium. When the dopant is zirconium (Zr), the ferroelectric material film may contain about 50 to about 80 at % zirconium.

The paraelectric material film may have paraelectric properties. The paraelectric material film may include, for example, at least one of silicon oxide and metal oxide having a high dielectric constant. Although the metal oxide contained in the paraelectric material film may include, for example, at least one of hafnium oxide, zirconium oxide and aluminum oxide, but the present disclosure is not limited thereto.

The ferroelectric material film and the paraelectric material film may include the same material. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film is different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 to about 10 nm, the present disclosure is not limited thereto. Because a critical thickness exhibiting the ferroelectric properties may be vary based on a type of the ferroelectric material, the thickness of the ferroelectric material film may vary depending on the type of the ferroelectric material.

In some embodiments, each of the main gate insulating film 430a and the dummy gate insulating film 430b may include one ferroelectric material film. In another embodiment, each of the main gate insulating film 430a and the dummy gate insulating film 430b may include a plurality of ferroelectric material films spaced apart from each other. Each of the main gate insulating film 430a and the dummy gate insulating film 430b may have a stack structure in which a plurality of ferroelectric material films and a plurality of paraelectric material films are alternately stacked.

The main gate capping pattern 450a may be disposed on a top face of the main gate electrode 420a and a top face of the main gate spacer 440a. The dummy gate capping pattern 450b may be disposed on a top face of the dummy gate electrode 420b and a top face of the dummy gate spacer 440b. Each of the main gate capping pattern 450a and the dummy gate capping pattern 450b may include, for example, at least one of silicon nitride (SiN), silicon oxynitride (SiON), silicon oxide (SiO₂), silicon carbonitride (SiCN), silicon oxycarbonitride (SiOCN), and combinations thereof.

The semiconductor device according to some embodiments may further include a source/drain pattern 460. The source/drain pattern 460 may be disposed on a side face of the main gate structure MGS or a side face of the dummy gate structure DGS.

The source/drain pattern 460 may include an epitaxial pattern. The source/drain pattern 460 may be disposed in a source/drain area of a transistor using the main active pattern MAP or the dummy active pattern DAP as a channel area thereof.

The semiconductor device according to some embodiments may further include an etch stop film 465. The etch stop film 465 may be disposed on a top face of the source/drain pattern 460, a sidewall of the main gate structure MGS, and a sidewall of the dummy gate structure DGS. Although not shown, the etch stop film 465 may be disposed along a sidewall of the source/drain pattern 460 and a top face of the field insulating film 405. The etch stop film 465 may include, for example, a material having an etch selectivity with respect to the first interlayer insulating film 470. The etch stop film 465 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The first interlayer insulating film 470 may be formed on the source/drain pattern 460 and the field insulating film 405. The first interlayer insulating film 470 may be disposed between adjacent main gate structures MGS or between adjacent dummy gate structures DGS. A top face of the first interlayer insulating film 470 may be coplanar with each of a top face of the main gate capping pattern 450a and a top face of the dummy gate capping pattern 450b.

The first interlayer insulating film 470 may include, for example, at least one of silicon oxide, silicon nitride, silicon oxynitride, and a low dielectric constant material. The low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof, but the present disclosure is not limited thereto.

The second interlayer insulating film 480 may be disposed on the first interlayer insulating film 470. The second interlayer insulating film 480 may be disposed on the main gate capping pattern 450a and the dummy gate capping pattern 450b. The second interlayer insulating film 480 may cover the first interlayer insulating film 470, the main gate capping pattern 450a, and the dummy gate capping pattern 450b. The second interlayer insulating film 480 may include, for example, at least one of silicon oxide, silicon nitride, silicon oxynitride, and a low dielectric constant material.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

1. A lithography process, comprising:
lithographically patterning first through fourth photoresist regions on respective first through fourth regions of a semiconductor substrate, in sequence, using a mask comprising:
a main area in which a main pattern is defined;
a first dummy area in which a first dummy pattern is defined, said first dummy area at least partially surrounding the main area; and
a second dummy area in which a plurality of second sub-dummy patterns are defined at corresponding corners of the mask that are spaced apart from the first dummy area; and
wherein said lithographically patterning the first through fourth photoresist regions comprises exposing at least part of the second dummy area on the first region of the substrate at least three times using the mask.

2. The lithography process of claim 1, wherein a width of the second sub-dummy patterns is greater than a width of the first dummy pattern; wherein the main pattern includes a main gate pattern; wherein the second dummy pattern includes a second dummy gate pattern; and wherein a width of the second dummy gate pattern is greater than a width of the main gate pattern.

3. The lithography process of claim 2, wherein the width of the main gate pattern is in a range from 1 nm to 90 nm.

4. The lithography process of claim 2, wherein the width of the second dummy gate pattern is in a range from 100 nm to 150 nm.

5. The lithography process of claim 1, wherein the main pattern includes a main active pattern; wherein the second dummy pattern includes a second dummy active pattern; and wherein a width of the second dummy active pattern is greater than a width of the main active pattern.

6. The lithography process of claim 1, wherein a width of the second dummy area is in a range from 7 μm to 10 μm.

7. The lithography process of claim 1, wherein a size of the second dummy area is in a range of 49 μm² to 100 μm².

8. The lithography process of claim 1, wherein the mask includes first to fourth areas arranged in a first direction; wherein each of the first to fourth areas extends in a second direction intersecting the first direction; wherein the first area entirely overlaps the second area in the first direction; wherein a portion of the third area protrudes, in the second direction, from an end of the second area; and wherein the fourth area entirely overlaps the third area in the first direction.

9. The lithography process of claim 8, wherein the second sub-dummy patterns are respectively disposed in a first corner of the first area, a second corner of the second area, a fourth corner of the second area, and a third corner of the third area, but not in the fourth area.

10. The lithography process of claim 8, wherein the second dummy area is not disposed in: a boundary area between the first area and the second area, a boundary area between the second area and the third area, and a boundary area between the third area and the fourth area.

11. An extreme ultra-violet (EUV) lithography process, comprising:
lithographically patterning first through fourth photoresist regions on respective first through fourth regions of a semiconductor substrate, in sequence, using a mask comprising:
a main area in which a main pattern is defined;
a first dummy area in which a first dummy pattern is defined, said first dummy area at least partially surrounding the main area;
a second dummy area in which a plurality of second sub-dummy patterns are defined at corresponding corners of the mask that are spaced apart from the first dummy area; and
an alignment area including an alignment pattern therein that is spaced farther from a center of the main area relative to the first and second dummy areas; and
wherein said lithographically patterning the first through fourth photoresist regions comprises exposing at least part of the alignment area on the first region of the substrate at least three times to EUV light, using the mask.

12. The lithography process of claim 11, wherein a perimeter of the mask is generally rectangular-shaped, but with three square-shaped cutouts at first, second and third corners of the mask; and wherein the alignment area extends as a protrusion from the fourth corner of the mask.

13. The lithography process of claim 12, wherein the alignment pattern is in the shape of a cross sign.

14. The lithography process of claim 13, wherein a center of the alignment pattern is aligned to: (i) a first side of the mask extending in a first direction, and (ii) a second side of the mask extending in a second direction orthogonal to the first direction.

15. An extreme ultra-violet (EUV) lithography process, comprising:
lithographically patterning first through fourth photoresist regions on respective first through fourth regions of a semiconductor substrate, in sequence, using a mask having a generally rectangular-shaped perimeter, but with three square-shaped cutouts at first, second and third corners of the mask, and an alignment area that extends as a protrusion from the fourth corner of the mask.

16. The lithography process of claim 15, wherein a portion of the photoresist on the first region of the semiconductor substrate is exposed at least three times to EUV light during said lithographically patterning.

17. The lithography process of claim 16, wherein the alignment area includes a cross-shaped alignment pattern therein.

18. The lithography process of claim 17, wherein a center of the alignment pattern is aligned to: (i) a first side of the mask extending in a first direction, and (ii) a second side of the mask extending in a second direction orthogonal to the first direction.

19. The lithography process of claim 16, wherein the mask includes a plurality of dummy patterns extending between first and second ones of the square- shaped cutouts.

20. The lithography process of claim 19, wherein the mask includes a plurality of dummy patterns extending between a third one of the square-shaped cutouts and the alignment area.

21.-40. (canceled)
